(19) United States
(12) Patent Application Publication
(10) Pub. No.: US 2012/0037771 A1
(43) Pub. Date: Feb. 16, 2012

(54) Apparatus and Method for Attaching Peripheral Devices to a Computer

(76) Inventor: Michael S. Kitchen, Charleston, SC (US)

(21) Appl. No.: 13/207,657

(22) Filed: Aug. 11, 2011

Related U.S. Application Data
(60) Provisional application No. 61/372,569, filed on Aug. 11, 2010.

(51) Int. Cl. H05K 7/00

(52) U.S. Cl. 248/223.41

(57) ABSTRACT

A device that forms a physical attachment or connection between a laptop or tablet type portable computer and a peripheral device. The invention according to one structure performs as a clip or holder type device that may be selectively attached to, and variably positioned on, the edge of a laptop or tablet computer screen or body of a laptop or tablet computer. Similarly, the device provides a means of attachment to one or more accessories, peripheral, or ancillary devices used in conjunction with operation of the lap top or tablet computer. The connection or attachment has sufficient strength and grip to maintain a physical connection between the laptop or tablet computer and the accessory device to allow the computer to be moved, carried or otherwise be repositioned during normal use without disruption of the physical connection, but not so strong or permanent that it cannot be easily broken using manual force.

### FIELD OF THE INVENTION

The field of the invention generally relates to computers and computer accessories, and more specifically, to a device for mounting accessories or computer peripherals to a computer.

### BACKGROUND OF THE INVENTION

Current practice involving the use of laptop computers often involves attaching a peripheral device to the computer to perform tasks, Devices that are often attached to laptop or tablet type computers may include but are not limited to: external and portable memory storage devices (hard drives), cellular telephones, digital media players, gaming devices and conventional writing tablets (paper) or printed materials. There is currently no easy to use solution that allows the operator to physically attach the peripheral device(s) to the laptop or tablet computer while in use and selectively detach the peripheral device(s) when finished. Many peripheral devices are connected to the laptop or tablet computer utilizing a USB connection which is typified by a cord of variable length that connects the peripheral device to the computer. When the operator picks up the computer to move it to a different location (for instance moving the computer from desk to a lap position to more easily access the keyboard or other means of input interface) the peripheral device inadvertently is left dangling from its USB connection cord or detaches from the cord falling unsupported to the desk or floor. This condition can lead to damage to the peripheral device(s), loss of data through ill timed disconnection, and certainly inconvenience for the operator.
There is a need for a device that can attach a peripheral device or accessory to a laptop or tablet type computer during operation.
There is a need for a means of protecting computer peripherals and accessories from unintended damage when the computer to which the device is connected is moved during normal operation.
There is a need for a means of physically attaching a peripheral or accessory to a laptop or tablet computer that is easily reversible.
There is a need for a means to attach peripherals or accessories to a laptop or tablet type computer and position the peripheral or accessory to enhance work place productivity.
There is a need for a means of attaching generic peripheral and accessory devices to a generic laptop or tablet computer wherein the physical attachment is made in a generic manner; capable of forming a reversible attachment between wide varieties of device designs made by a wide variety of manufacturers.

### SUMMARY OF THE INVENTION

The invention is a device that forms a physical attachment or connection between a laptop or tablet type portable computer and a peripheral device. The invention according to one structure performs as a clip or holder type device that may be selectively attached to, and variably positioned on, the edge of a laptop or tablet computer screen or body of a laptop or tablet computer. Similarly, the device provides a means of attachment to one or more accessories, peripheral, or ancillary devices used in conjunction with operation of the lap top or tablet computer.

The connection or attachment has sufficient strength and grip to maintain a physical connection between the laptop or tablet computer and the accessory device to allow the computer to be moved, carried or otherwise be repositioned during normal use without disruption of the physical connection. The physical connection is not so strong or permanent that it cannot be easily broken using manual force. The operator may position the device in a variety of ways on the laptop or tablet and position one (or more) peripheral devices in a variety of positions utilizing the device.

The device may provide sufficient dimensional sizing of receiving channels to allow placement and retention of accessories, laptop, or tablet devices of varied thickness and varied edge profiles. This capability is enhanced through the inclusion of elastic, compressible contact components that permit application of relatively constant compressive or friction force on device surfaces across widely varied cross-sectional dimensions.

### DESCRIPTION OF THE DRAWINGS

FIG. 1 is a perspective view showing the invention attached to a computing device and also attached to an accessory.

FIG. 2a is a side elevation of the invention.

FIG. 2b is a cross-section of the invention.

FIG. 3a is an isolation of compressible gripping members, which may be Individual contact fingers of uniform length supported by an elastic membrane

FIG. 3b is an embodiment of compressible gripping members, which may be individual contact fingers of non-uniform length.

FIG. 4 is an embodiment of compressible gripping members which may be individual fingers of non-uniform graduated lengths increasing in length horizontally across surface of elastic support.

FIG. 5 is an end elevation showing compressible gripping elements positioned to contact both upper and lower surfaces of the engaged device.

FIG. 6 is an oblique view with tapered vane shaped gripping elements supported by an elastic membrane.

FIG. 7 is another embodiment of compressible gripping member having an elastic “bump” of solid or composite construction supported by an elastic membrane.

FIG. 8a is an elevation of the invention with the compressible gripping members of FIG. 7.

FIG. 8b is an elevation of the invention of FIG. 7 showing a computing device or computing accessory inserting therein.

FIG. 9 is a partial view of the invention as shown in FIGS. 1 and 2.

FIG. 10 is a partial view of the invention demonstrating elastic deformation of the gripping fingers as shown in FIGS. 1 and 2.

FIG. 11 is a partial view of the invention with tapered vane gripping members as shown in FIG. 6, and having a hinged middle section.

FIG. 12 is a perspective view of the invention showing a central portion designed to receive a device cord and provide a spool mechanism onto which a conductive cord may be wound.

FIG. 13 is a perspective view of the invention having tapered gripping fingers at upper surface of receiving channel and formed “guide rails” along non-gripping surfaces of receiving channel.

FIG. 14 is a perspective view of the invention having a spring biased mechanism for gripping.

FIG. 15 is an end elevation of the invention with an elastic hinged cross-section providing spring actuated gripping mechanism.

FIG. 16 demonstrates the invention of FIG. 15 in use.

FIG. 17 is an additional view of the invention as shown in FIG. 15 showing “guide rails” at bottom surface and hinged elastic spring gripping mechanism at upper surface of receiving channel.

FIG. 18 is a perspective view of the invention having a hinge mechanism capable of rotating 180 degrees, with tapered elastic finger gripping members of variable length shown at upper and lower surfaces of the receiving channel.

FIG. 19 is a perspective view of the invention demonstrating two identical units of the invention rotated at 90 degrees to each other, with guide rails shown oriented perpendicularly to the axis of the receiving channel.

FIG. 20 is a perspective view of the invention with a centrally located hinge mechanism.

FIG. 21 is an end elevation of the invention showing the hinge mechanism partially opened and a computer related device engaged within one of two receiving channels.

FIG. 22 is a perspective view of the invention showing a central portion designed to receive a device cord and provide a spool mechanism onto which a conductive cord may be wound.

### DESCRIPTION OF PREFERRED EMBODIMENTS

The invention provides a device for forming a physical fixed connection between a laptop or tablet type computer and a peripheral device used in conjunction with the computer that is capable of maintaining the physical connection when the laptop or tablet is subjected to movement or repositioning encountered in common usage of the computer. This connection helps avoid the unintended dropping or disconnection (such loss of as a digital connection established with a flexible cord) of peripherals or accessories as the operator moves the computer.

Preferred embodiments provide a channel, slot or pocket that is sized to provide a spatially defined clamping, gripping, elastic entrapment, and/or frictional contact area within a volume of space to receive an edge, portion or volume that is intrinsic to the physical characteristics of the laptop, tablet, peripheral or accessory device. These areas may be designed to provide a receiving space that is generically capable of accommodating a variety of sizes or shapes, or may be so designed that the spatially defined receiving area is intended to accommodate a specific device that is held in position. In some embodiments, the portion of the invention that receives the laptop or tablet reflects specific product design specifications. The portion of the invention that receives the peripheral or accessory is designed to accommodate the specifications of a specific product, or any combination of the two.

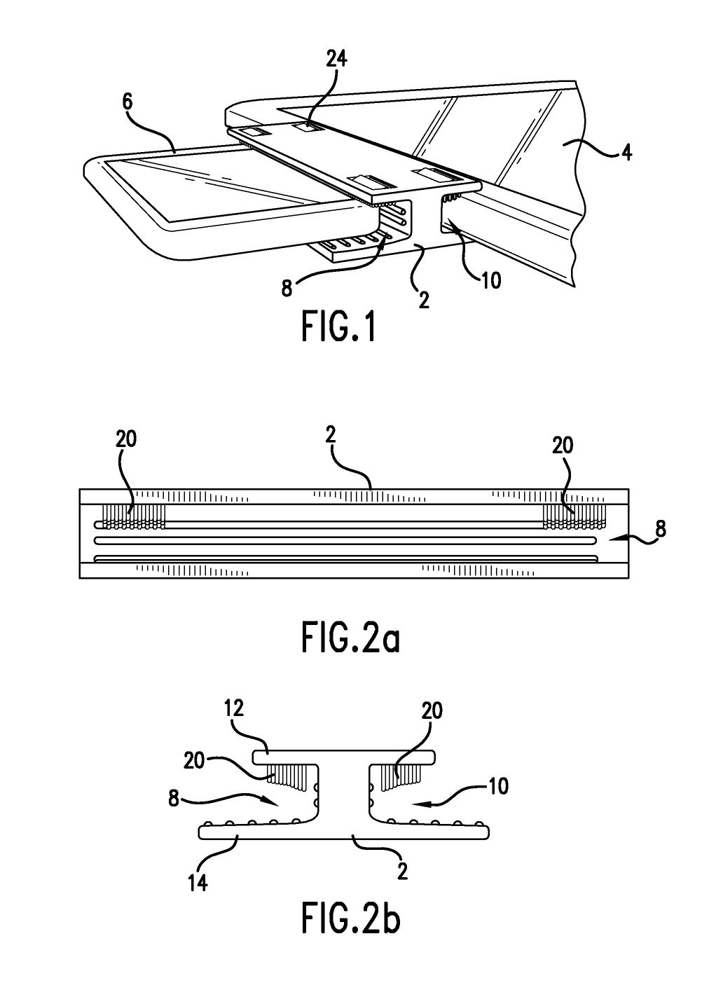

In some embodiments, the invention is a multiple sided, such as two sided, body 2 that acts as a clamp to provide an attachment to a laptop or tablet computer 4 and to an attachment a peripheral or accessory device 6. FIG. 1. This embodiment may have two opposed openings that are formed as “U” shaped channels 8, 10. One of the “U” shaped channels accommodates cross-section profiles of a portion of a laptop/tablet type computer and the other “U” shaped channel accommodates cross-section profiles of an accessory or peripheral device. FIGS. 1,5,14,15,16. For example, the channel may be configured to accommodate devices having thicknesses in excess of 22 millimeters while through the elastic characteristics of the gripping components still have the capacity to grip devices as thin as 5 mm in thickness. The channels may be of reduced dimension, or tapered, where they join the center of the body, so as to provide spacing and prevent the side of the computer related device from being obstructed in an manner that would interfere with ventilation of the computer related device, or with controls that may be mounted on the side of the computer related device.

In an embodiment, the arms 12, 14 of one or both “U” shaped channels of the body are of unequal length. The lower arm is longer to provide additional support in resisting gravitational pull, providing a longer arm to resist the moment or torquing of the device relative to the clamp due to gravity or other forces, and to spread the force of the held device over the arm. The upper arm of the “U” shaped channel(s) is shorter so as to not interfere with use or viewing of the held object, such as the laptop or pad and the accessory.

In another embodiment, the opposing “U” shaped channels are pivotally connected and pivot relative to each other. FIGS. 5,11. The body comprises a hinge 16 positioned between the channels. The hinge may be constructed and arranged to allow motion around a single axis. In another embodiment, the hinge is polyaxial, such as a ball and joint, allowing motion in all axes. The hinge may be constructed as a malleable or “gooseneck” connection providing for motion in all axes. The hinge may be constructed to allow the “U” shaped channels to be positioned parallel to each other, to effect folding of the invention.

Within a spatially defined area of each “U” shaped channel, one or more gripping mechanisms 20 may be present. The gripping mechanism firmly holds the peripheral or accessory device within the channels. Attachment can be easily reversed using manual force. The gripping members are preferred to be compressible. The gripping members may extend longitudinally along the interior surfaces of the “U” shaped channels. FIG. 2a, 13, 17, 20. The gripping members may extend laterally from the interior walls of the “U” shaped channels and into the interiors of the “U” shaped channels. FIGS. 2,5,8,9,10,14,15.

In some embodiments, the invention comprises two “U” shaped component areas with elastic or compressible contact portions within each “U” shaped channel. FIGS.1,2,5,13,17. The body may be a generally rigid frame into which two or more readily compressible/deformable and/or elastic contact pads are located. Preferably, the body of this embodiment is formed of a relatively rigid but somewhat flexible material, such as a plastic, that can be molded or formed using known plastic molding or forming processes. The rigid plastic material is preferred to be sized and structurally shaped so that material bending of this part of the invention does not occur under anticipated loads encountered in the process of placing a device within the channel or under loading anticipated in supporting the device(s).

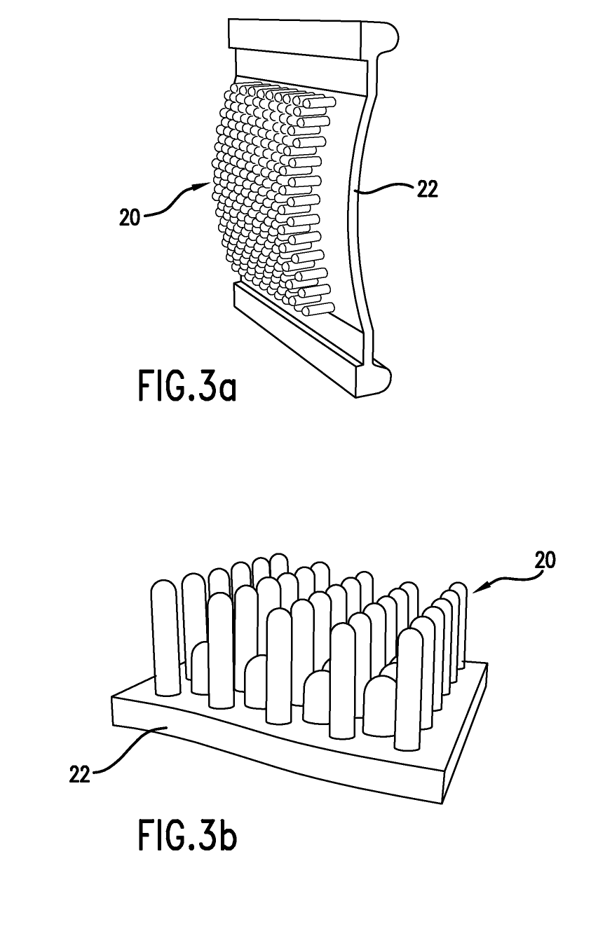

The structure of pads, such as elastic pads, which assist in holding, clamping or gripping, may be varied to accommodate varied cross-sectional thicknesses of the laptop/tablet profile, as well as various peripheral and accessory devices. The mechanical properties of the pads may be varied by altering the size and thickness of the pads. These properties may be selected to allow for variations in cross-sectional height, while providing relatively consistent clamping or gripping force across a wide variety of profile heights. Furthermore, the gripping pads may be constructed with surface profiles that undergo deformation upon placement of a peripheral, accessory, or laptop/tablet profile within the “U” shaped channel. The designed deformative properties of the pads may be obtained through the use of elastic finger like or vane like projections from the pad. FIGS. 3,4,5,6,7,10,11,13,18. The profiles of the clamping or gripping pads may be tapered in one or more directions favoring ease of insertion of the device profile from one or more directions while providing greater clamping or gripping force as the device is moved further across the surface of the clamping or gripping pad. FIGS. 2,4,6,7,11.

The “U” shaped channels may have additional design elements that provide easy insertion of the computing device or accessory. Rounded or tapered edges may be structured and arranged to guide insertion of cross-sectional profiles. FIGS. 2,11,17,19,20. In addition to those areas within the “U” shaped channel intended for provide clamping or gripping contact areas, the inner surfaces of the “U” shaped channel may be comprised of additional contact areas having elastic non-marring composition. These areas may be guide rails or tracks upon which the surface of the peripheral, accessory, or laptop/tablet device will slide at placement into, or removal from, the “U” shaped channel.

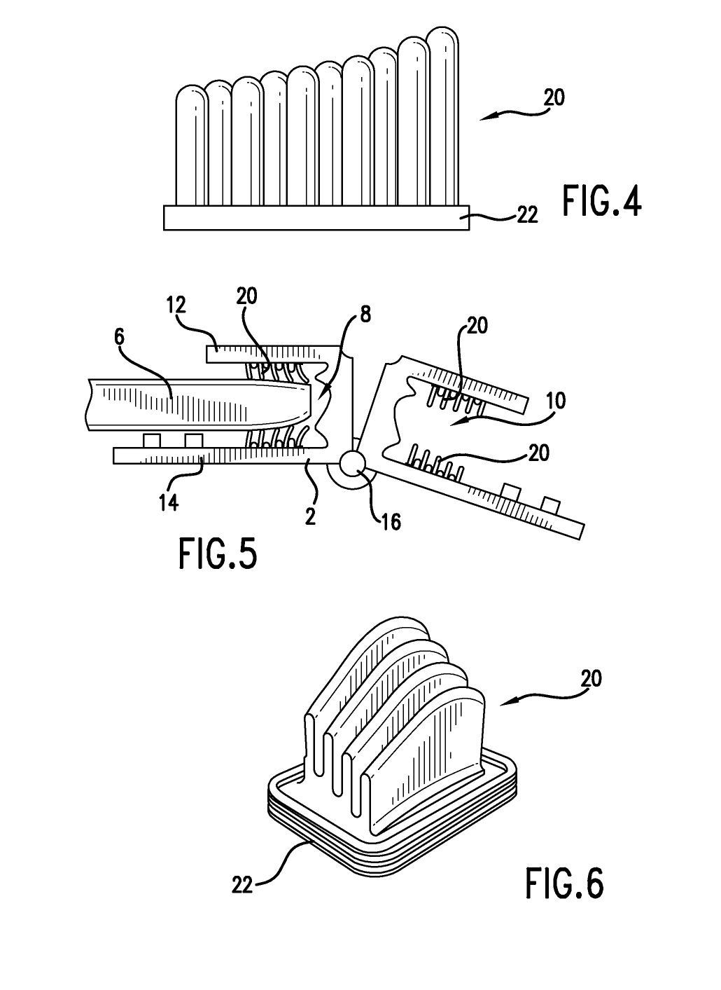

In another embodiment, flexible pads having elongated fingers are used. The contact pads may be comprised of flexible finger like projections that directly contact and grip the surface of the inserted laptop, computing tablet, peripheral, or accessory device. FIGS. 5,9,10,18. The compressible gripping member of FIG. 3a shows a plurality of flexible fingers. The fingers may extend from a backing pad or membrane and may be of uniform height. The compressible gripping member of FIG. 3b has a plurality of flexible fingers. The fingers may extend from a backing pad or membrane and may be of variable height and diameter. The compressible gripping member of FIG. 4 has a plurality of flexible fingers. The fingers may extend from a backing pad or membrane and may be formed to provide a tapered profile. As mounted in the channel of the body, the computing device or accessory first contacts the shorter fingers, with the fingers providing increasing resistance as the device is inserted into the channel of the body. The finger-like projections may be of uniform length or height (FIG. 3) or may be of variable length or height such that when the contact pad is viewed “en block,” there is a tapered profile. FIGS. 2,4,13. The finger-like projections may additionally be constructed with varied cross-sections. For example, a pad may be comprised of a plurality of finger-like projections having some projections that are of a smaller diameter than other finger-like projections. These variations may be arranged in a pattern. FIGS. 3,5. This arrangement provides support between finger-like projections as they are deformed upon insertion of a device.

In another embodiment, the flexible pads are comprised of vane-like projections that may be constructed of flexible material, such as plastic, that directly contact the laptop, tablet, peripheral or accessory device that is inserted into, for example, a “U” shaped channel component of the invention. The compressible gripping member of FIG. 6 has a plurality of flexible vanes. The vanes may extend from a backing pad or membrane and may be formed to provide a tapered profile in two (2) directions. The segments or vanes of the contact pad may be tapered in one or more directions. FIGS. 6, 11. The linear characteristic of vane like projections allows for biased structural characteristics whereby the vane may be easily deformed by a force exerted perpendicular to its long axis, but offers significantly greater resistance to deformation to force applied along its long axis. The flexible vanes may be mounted to a flexible membrane that allows deformation through to the outside of the “U” shaped channel as a device is inserted.

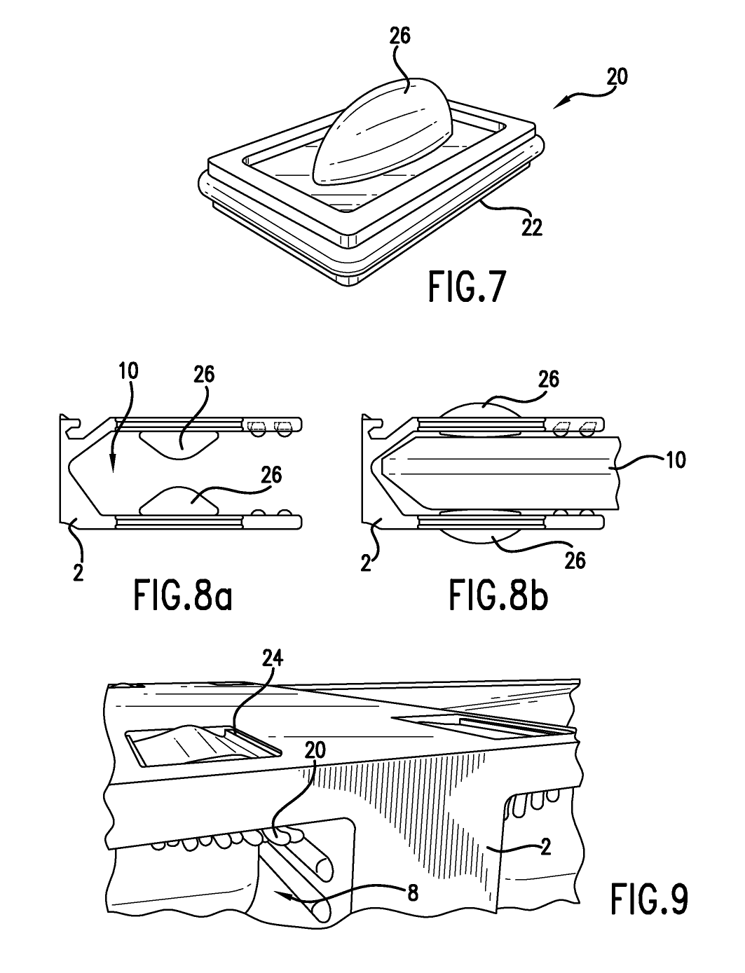

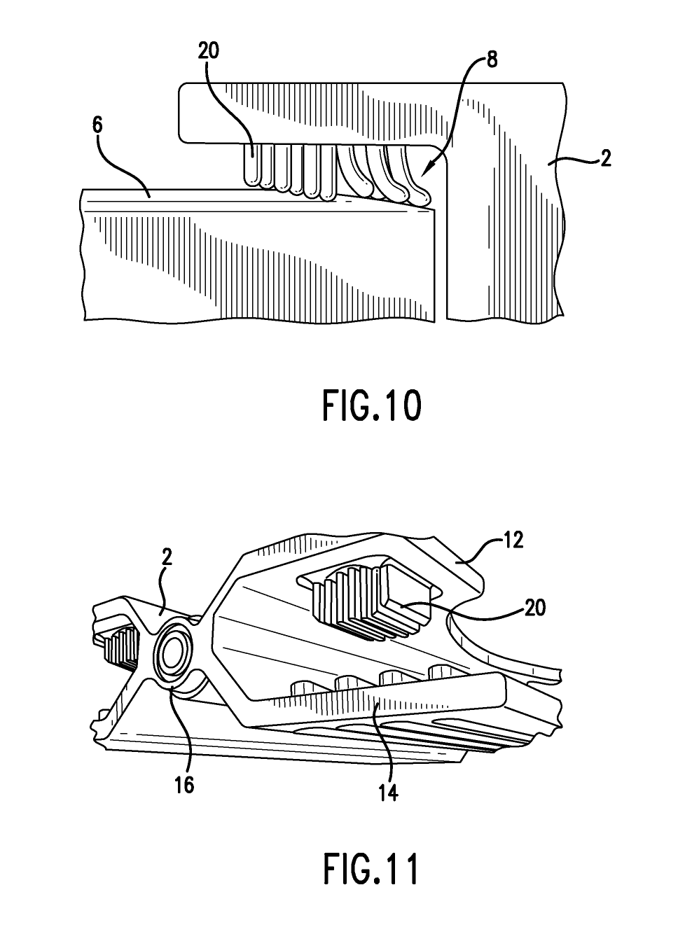

In another embodiment, the contact pad may be configured with a single wafer of ellipsoid geometry. FIG. 7. A wafer-like structure that is similar to previously described configurations may be tapered in one or more directions. The wafer or ellipsoid contact pad may be constructed with a hollow center, providing less resistance to compression as compared with a solid construction.

In another embodiment, the pads are comprised of a flexible and expandable material filled with a flowable material that may be a gas or a viscous fluid. The flowable material may be compressed manually to form a bubble 26 in the flexible and expandable material. When the device according to this embodiment is inserted into the “U” shaped channel, the pad is compressed and the flowable material is forced to flow outward through a channel. FIG. 8. This configuration has an expandable chamber outside of the “U” shaped channel into which the flowable material moves upon insertion of the device. The increased pressure resulting from the force on the flowable material within the container applies retaining pressure on the device to retain the device within the channel.

In any of the embodiments, the compressible gripping members may be positioned or mounted within a void 24 formed in the arms of the “U” shaped channels. The compressible gripping members can be pushed by larger computer related devices into the void so as to be accepted within the channels, while still providing a gripping force on the object. As shown in FIG. 9, the fluid is pushed through the void and above the arm by the computer related device.

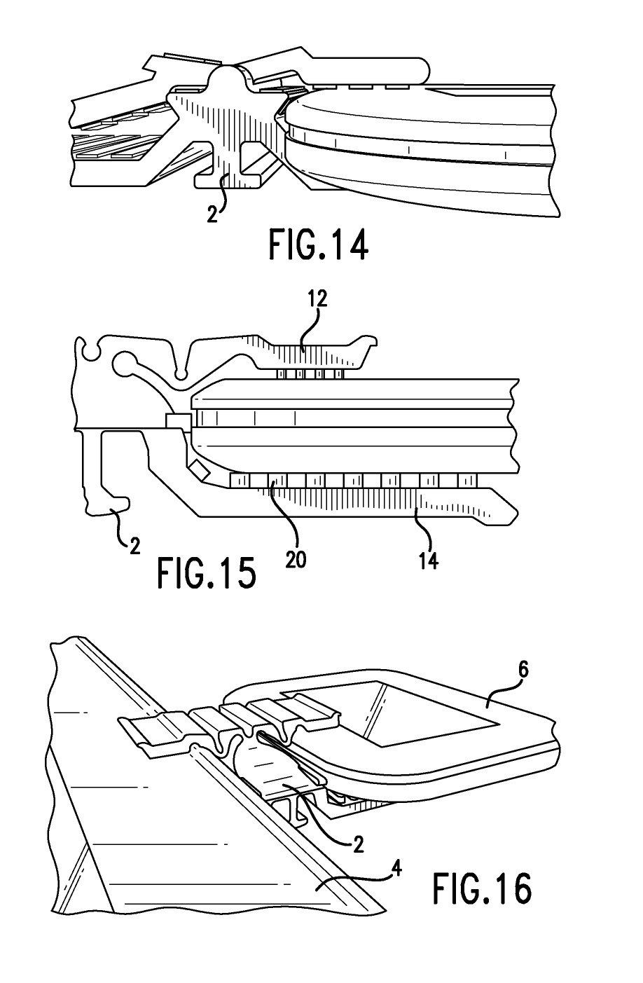

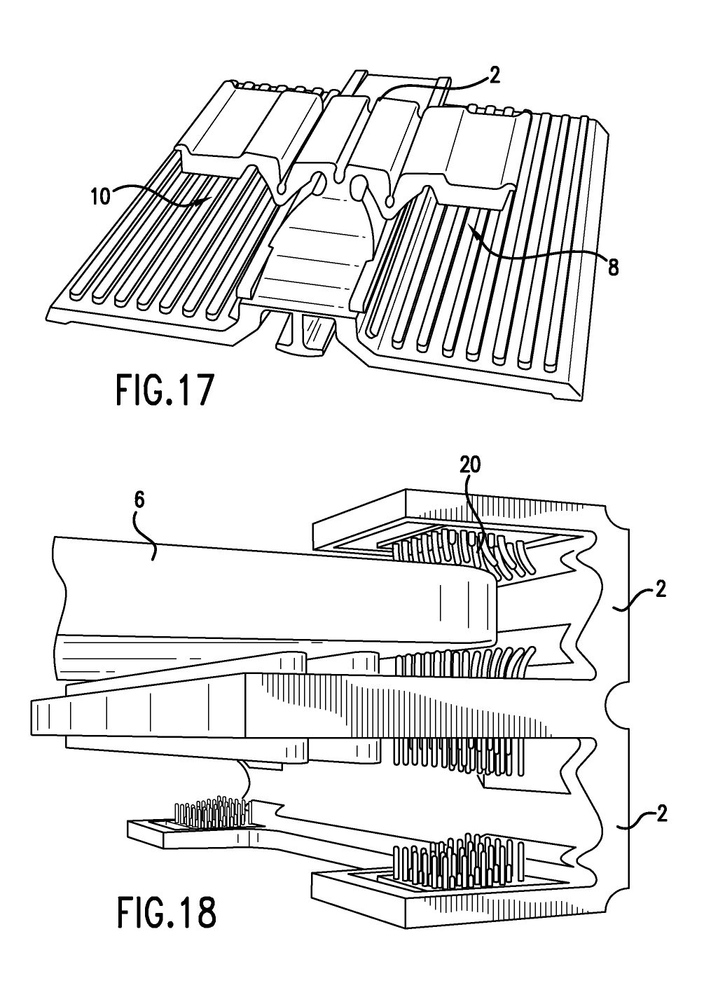

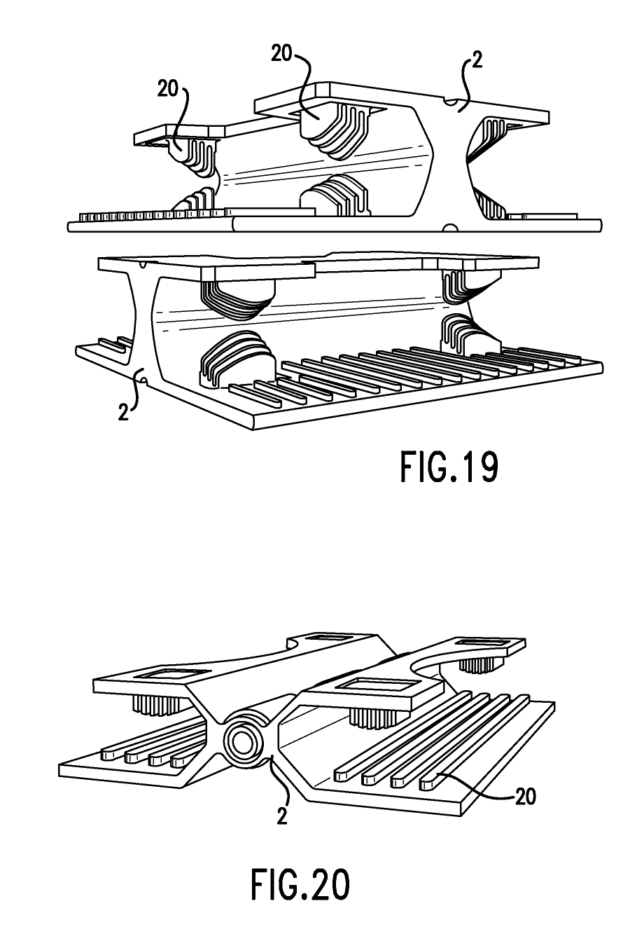

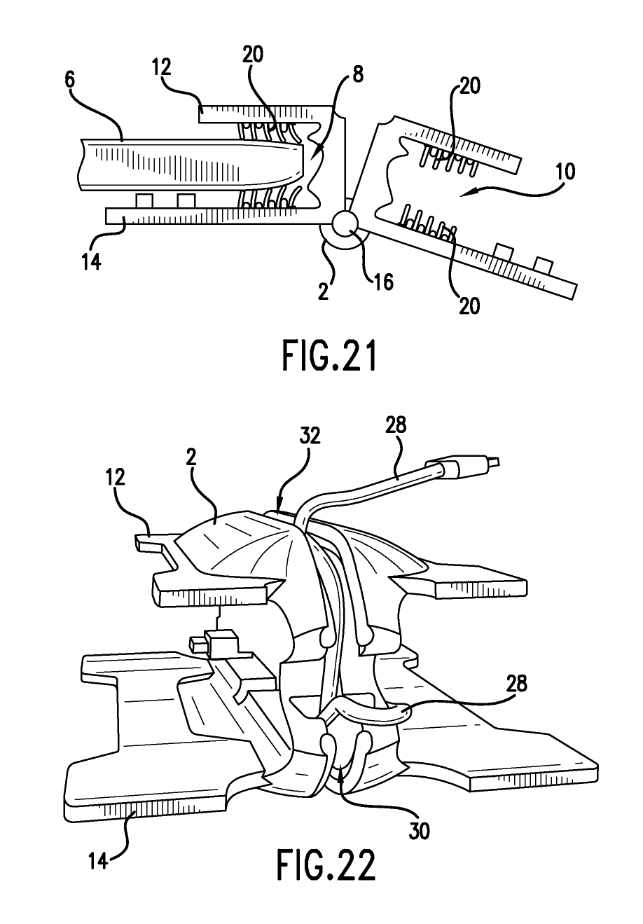

In another embodiment, the device is configured with spring biased clamping structures. Compression force may be applied by fulcrum pivoted levers to open the “U” shaped channel components of the invention. FIG. 14. The spring mechanism may be constructed of elastic or plastic material, or be made of metal construction.

In another embodiment, one or both legs of the “U” shaped channel may be constructed of elastic material capable of deforming to allow insertion of laptop, tablet, peripheral, or accessory device and maintaining a compressive force across the profile of said device sufficient to hold the two devices in proximity. The profile of the elastic portion of this design may be so sized that bending of the elastic plastic material occurs at selected areas where structural attenuation occurs. FIGS. 15,16,17. In a roughly sigmoidal configuration, this design provides for the outermost portion to adapt in conformation to match the profile of the inserted device.

The basic geometric configuration and mechanisms described herein for use as a clamp between laptop or tablet computer and various peripheral or accessory devices may be applied to a number of related applications. The basic channel geometry may be applied to the edge of a portable computer stand where the stand and computer is intended to be moved in operation as a single unit. The channel component may be manufactured as an integral part of a portable stand, or alternately produced as an add-on component, wherein the channel may be permanently affixed to the stand, or reversibly affixed.

The “U” shaped channel is formed to receive a variety of differing profiles that are received and clamped, gripped or frictionally held. The variety of profiles may e represented by multiple model designs from a single manufacturer or a variety of designs represented by a variety of different manufacturers. The mechanical clamping, gripping, or frictional contact area is sized to provide space for the laptop, tablet, peripheral, or accessory to move into or through the “U” shaped component while providing sufficient force to retain the device without causing damage to the device. The “U” shaped component(s) may be constructed and arranged to receive a specific profile or edge of a proprietary laptop, tablet, peripheral or accessory device; whether this be a common or similar profile design reflecting a family of different models made by a single manufacturer or be limited to a specific profile design reflective of a single model by a single manufacturer. The compressive force between the two legs of the “U” shaped channel is effective for clamping, or gripping the edge of the device(s). The clamping or gripping force may be provided through the elastic material properties of certain plastics that will provide sufficient holding force when a device is placed into the “U” shaped channel, while providing great enough distensibility that a variety of device profile depths may be accommodated.

The compressible gripping member may be formed on a pad 22. The compressible gripping member may comprise a wedge shaped geometry in one or more directions, providing for greater space between portions of the compressible gripping member and an opposing compressible gripping member or opposing surface of the opposite arm of the “U” shaped channel component, or wherein the compressible gripping member(s) are distributed upon a single arm of the “U” shaped channel component. The compressible gripping members may be: a single member or single opposed pair positioned longitudinally along the long axis of the “U” shaped component; a plurality of members positioned longitudinally along the long axis of the “U” shaped component; formed as flexible fingers of consistent length or flexible fingers of variable length; formed as parallel vanes of consistent or variable dimension and structural characteristics that are oriented parallel or perpendicular to the long axis of the “U” shaped channel; formed as vanes having a wedge shaped geometry in one or more directions; formed as an air or fluid filled “bubble” that is compressed upon introduction of a device into the “U” shaped channel; comprised of a single “wafer” formed of flexible plastic. FIGS. 8, 9.

The channel clamping or gripping mechanism as herein described may be formed as an integral part of cooling pad devices for use with laptop computers. In this instance, the clamping or gripping technology may be located within channel areas formed at the edge of the cooling pad. Alternately, clamping or gripping mechanisms with contact pads and deformable elastic materials described may be integrated into pockets or sleeves formed within the cooling pad devices. The pockets may be configured so that a portion of the air flow from the cooling pad fan may be channeled to move across the peripheral or accessory devices placed within the pocket, or additional fans may be placed in the design to provide cooling for the peripheral or accessory devices.

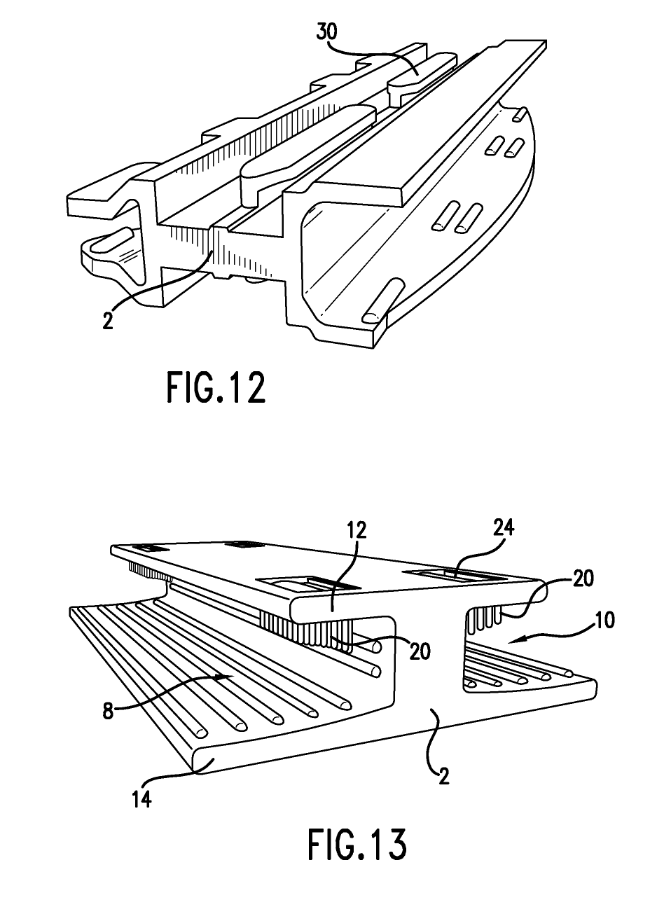

In another embodiment, the invention includes a provision for a spool mechanism 30 that is capable of receiving and storing a conductor 28, such as excess power cord length or cord length used to connect the accessory to the laptop or tablet type computer. The spool component of the device comprise one or more spindles or defined winding surfaces having the capacity to accommodate winding of connection cords of variable lengths. Further the spool mechanism may be configured to aid in retaining the wound excess cord in a variety ways. For example, the spindle portion of the may provide a “cap” of larger surface area than the spindle cross-section to prevent loops of wound cord from slipping off of the spindle. FIG. 12. Alternatively, the spindle portion of the device may comprise a central core of a generally torus configured chamber forming the central bridging portion of the device. A gap may be provided in a circumferential manner around the torus shaped chamber, with edges of the circumferential chamber formed of elastic material to allow the operator to wind excess cord through the elastic gap. The cord is thereby wound around the central spindle portion of the device. FIG. 22. Introduction of the excess cord into the torus shaped spindle chamber may be facilitated through provision of one or more cutaways 32 to, or gaps in, the torus chamber.

What is claimed:

1. A device for attaching articles to a computer, comprising a body, the body comprising a first U shaped channel and a second U shaped channel, the first U shaped channel having an opening that is opposite the opening of the second U shaped channel, wherein the first U shaped channel is constructed and arranged to receive a cross section profile of a portable computing device; and wherein each of the first U shaped channel and the second U shaped channel comprises a plurality of compressible gripping members, and wherein the plurality of compressible gripping members are positioned internally in the first U shaped channel and the second U shaped channel.

2. A device for attaching articles to a computer as described in claim 1, wherein the first U shaped channel comprises a longer lower arm and a shorter upper arm.

3. A device for attaching articles to a computer as described in claim 1, wherein each of the first U shaped channel and the second U shaped channel comprises a longer lower arm and a shorter upper arm.

4. A device for attaching articles to a computer as described in claim 1, wherein the plurality of compressible gripping members comprises a plurality of fingers that extend into the second U shaped channel.

5. A device for attaching articles to a computer as described in claim 1, wherein the plurality of compressible gripping members comprises a plurality of fingers that extend into the second U shaped channel, and wherein the plurality of fingers are of multiple lengths.

6. A device for attaching articles to a computer as described in claim 1, wherein the plurality of compressible gripping members comprises a plurality of fingers that extend into the second U shaped channel, and wherein the plurality of fingers are of multiple lengths and the plurality of fingers comprise a tapered profile.

7. A device for attaching articles to a computer as described in claim 1, wherein the plurality of compressible gripping members comprises an elastic chamber having a compressible fluid therein.

8. A device for attaching articles to a computer as described in claim 1, wherein the plurality of compressible gripping members comprises an elastic chamber having a viscous fluid therein.

9. A device for attaching articles to a computer as described in claim 1, wherein the plurality of compressible gripping members comprises an elastic chamber having a viscous fluid therein, wherein pressure from a device held within the second U shaped channel forces the viscous fluid to an exterior of the body.

10. A device for attaching articles to a computer as described in claim 1, wherein the first U shaped channel and the second U shaped channel are in a pivoting relationship with each other.

11. A device for attaching articles to a computer as described in claim 1, wherein the second U shaped channel comprises a generally rigid arm and a deformable arm.

12. A device for attaching articles to a computer as described in claim 1, wherein the plurality of compressible gripping members of the second U shaped channel are positioned within an opening of the body that extends from an exterior of the second U shaped channel to an interior of the second U shaped channel.
